(19) United States
(12) Patent Application Publication
(10) Pub. No.: US 2006/0267135 A1
(43) Pub. Date: Nov. 30, 2006

(54) Circuit arrangement placed on a substrate and method for producing the same

(76) Inventors: Eckhard Wolfgang, Munchen (DE); Franz Auerbach, Soest (DE); Bernd Gutsmann, Weyhe (DE); Thomas Licht, Warstein (DE); Nobert Seliger, Munchen (DE); Jorg Zapf, Munchen (DE)

Correspondence Address: STAAS & HALSEY LLP, SUITE 700, 1201 NEW YORK AVENUE, N.W., WASHINGTON, DC, 20005, US

(21) Appl. No.: 10/566,439

(22) PCT Filed: Jul. 12, 2004
(86) PCT No.: PCT/EP04/51458

§ 371 Date: Jan. 31, 2006

(30) Foreign Application Priority Data
Jul. 31, 2003 (DE) 103 35 153.1

(51) Int. Cl. H01L 29/00

(52) U.S. Cl. 257/528

(57) ABSTRACT

A circuit arrangement placed on a substrate has at least one semiconductor component arranged on the substrate and having at least one electrical contact surface and at least one connection line also arranged on the substrate and used to electrically contact the contact surface of the semiconductor component. The connection line forms part of a discrete, passive electrical component arranged on the substrate. The electrical contacting of the contact surface of the semiconductor component is carried out during a step of the process and the part of the secrete, passive electrical component is produced. To this end, especially a film consisting of an electrically insulating material is applied to the power semiconductor and to the substrate under a vacuum, and the contact surface of the power semiconductor is then bared. Furthermore, the connection component is carried out and the part of the discrete, passive electrical component is produced.

### CROSS REFERENCE TO RELATED APPLICATIONS

This application is based on and hereby claims priority to PCT Application No. PCT/EP2004/051458 filed Jul. 12, 2004 and German Application No. 10335153.1 filed on Jul. 31, 2003, the contents of which are hereby incorporated by reference.

### BACKGROUND OF THE INVENTION

The invention relates to a circuit arrangement placed on a substrate and comprising at least one semiconductor component arranged on the substrate and having at least one electrical contact surface and at least one connection line arranged on the substrate for electrically contacting the contact surface of the semiconductor component. In addition, a method for producing the circuit arrangement is specified.

A circuit arrangement of this kind and a method for producing this circuit arrangement are, for example, known from WO 03/030247 A2. The substrate is, for example, a DCB (direct copper bonding) substrate consisting of a ceramic carrier layer, to both sides of which electrically conductive copper layers are applied. A semiconductor component, for example, is soldered to these electrically conductive copper layers in such a way that a contact surface of the semiconductor component is provided facing away from the substrate. The semiconductor component is, for example, a power semiconductor component in the form of a MOSFET.

A film based on polyimide or epoxy is laminated under vacuum onto this arrangement of a semiconductor component and the substrate, so that the film with the semiconductor component and the substrate are closely joined. The film covers the semiconductor component and the substrate. Then, where the electrical contact surface of the semiconductor component is located, a window is produced in the film. The window is produced, for example, by laser ablation. Producing the window exposes the contact surface of the semiconductor component. Furthermore, an electrical contacting of the contact surface takes place. To this end, a mask, for example, that leaves the contact surface and the areas for the connection line to the contact surface exposed, is applied. A cohesive layer of an electrically conductive material is then generated on the contact surface and on the exposed areas of the film. The connection line for electrically contacting the contact surface of the semiconductor component is thus formed.

Several semiconductor components, or the contact surfaces of the semiconductor components, can be connected to each other via the described connection line to form an electrically-conductive connection. A discrete passive electrical component, for example a capacitor or coil, that may be required for the circuit arrangement must be mounted as a separate component on the substrate. Retrospectively fitting the discrete passive electrical component is, however, expensive.

### SUMMARY OF THE INVENTION

The object of this invention is to provide a construction of the circuit arrangement that is more compact compared with known prior art and to provide a simplified method for producing the circuit arrangement on the substrate.

To achieve this object, a circuit arrangement is provided on a substrate comprising at least one semiconductor component arranged on the substrate and having at least one electrically-conductive contact surface and at least one connection line for electrically contacting the contact surface of the semiconductor component arranged on the substrate. The circuit arrangement is thus characterized in that the electrical connection line forms part of at least one discrete passive electrical component arranged on the substrate.

To achieve the object, a method for producing the circuit arrangement by means of the following method steps is provided: a) provision of a semiconductor component on a substrate with an electrical contact surface that is facing away from the substrate, and b) production of the electrical connection line, with the contact surface of the semiconductor component being contacted and the part of the discrete passive electrical component being produced.

The semiconductor component can be a semiconductor component based on any semiconductor material. The semiconductor material is, for example, silicon or gallium arsenide. Silicon carbide (SiC) is particularly advantageous in this connection as a semiconductor material. Semiconductor components with a semiconductor material of this kind are particularly suitable for high-temperature applications.

In a particular embodiment, the semiconductor component is a power semiconductor component. The power semi-conductor component is, for example, a MOSFET, an IGBT or a bipolar transistor. Power semiconductor components of this kind are suitable for controlling and/or switching high currents (of several hundred A).

The power semiconductor components named are controllable. To this end, the power semiconductor components each have at least one input contact, one output contact and one control contact. In the case of a bipolar transistor, the input contact is normally called the emitter, the output contact the collector and the control contact the base. In the case of a MOSFET, these contacts are known as source, drain and gate.

Any organic-based or inorganic-based circuit carriers can be used as the substrate. Examples of such substrates are PCB (printed circuit board), DCB, IM (isolated metal), HTCC (high temperature cofired ceramics) and LTCC (low temperature cofired ceramics) substrates.

An electrical connection line (supply line) is generally regarded as a parasitic or distributed component. In the context of this invention, the discrete passive electrical component is not to be regarded as a parasitic electrical component. Instead, the discrete passive electrical component is to be regarded as a concentrated component, i.e. an idealized component.

The connection line forms the electrical contact to the contact surface of the semiconductor component. In particular, however, the connection line is additionally used to produce a discrete passive electrical component. A connection line is produced on the substrate that not only provides the electrical contacting of the contact surface of the semiconductor component, but also performs an additional function as part of a passive electrical component. To this end, the connection line is produced in such a way that the electrical contacting of the contact surface of the semiconductor component and the part of the discrete passive component are produced concomitantly. The large-surface contacting and wiring technique described in the introduction is used to arrange discrete passive electrical components on the substrate or to integrate these components into a multilayer structure arranged on the substrate.

In a particular embodiment, the discrete passive electrical component is a capacitor and the part is an electrode of the capacitor. During the production of the contacting of the contact surface of the component, an electrode of a capacitor is produced concomitantly. To complete the capacitor, a dielectric is, for example, applied in further steps to the connection line in the area of the electrode and in the area of the contact surface of the semiconductor component. To this end, a film, for example of an electrically insulating material with a specific dielectric constant is applied as a lamination. A counter-electrode of the electrode of the capacitor to be produced is then created on the film. The film provides the electrical insulation of the contact surface of the semiconductor component. The film also serves at the same time as a dielectric of the capacitor. A layer of dielectric material arranged between the electrode and the counter-electrode of the capacitor results. By repeated applications of layers of electrically conductive material and electrically insulating material, a multilayer capacitor, in particular, is possible in this manner.

In a further embodiment, the discrete passive electrical component is a coil and the part is a winding of the coil. A winding or a part of a winding of a coil is produced concomitantly with the production of the contacting of the contact surface of the component. A coil can be arranged on the substrate in this way in particular in a multilayer construction.

In a further embodiment, the discrete passive electrical component is an electrical resistor and the part is a wire resistor. An electrical resistor is produced concomitantly with the production of the contacting of the contact surface of the component. Each electrical connection line constitutes an electrical wire resistor per se. However, the lowest possible electrical resistance is usually desirable with an electrical connection line. The connection line used here is designed in such a way that the connection line itself performs the function of a necessary, external electrical resistor. For this purpose, for example, a specific electrically conductive material is used. Also, a defined diameter of the connection line is set to influence the electrical resistance of the connection line. It is possible in this way, for example, to not only provide the electrical contacting of the contact surface of the semiconductor component by means of the electrical connection line but also to provide an electrical fusible link for the circuit arrangement.

In a further embodiment, the discrete passive electrical component is a part of a sensor of a physical variable. By means of a current flow through the connection line, or through the discrete passive electrical component, a physical variable is generated that enables the current flow to be indicated, and vice versa the physical variable influences the current flowing through the connection line. With a known relationship between the current flow through the connection line and the physical variable, the physical variable can be determined.

Thus, a Hall sensor with the “magnetic field” physical variable can be realized. A current sensor with the “current” physical variable can also be integrated. For example, the current sensor consists essentially of an electrical transformer with at least two magnetically-coupled coils. The current flow through one of the coils generates a magnetic field that induces a current in the adjacent coil. An electrical signal is generated that enables the current flow to be indicated.

In particular, the sensor is a temperature sensor with the physical variable “temperature”. In a simplest case, the temperature sensor consists only of a passive electrical component in the form of an electrical wire resistor. The flow of the current through the resistor causes the temperature of the resistor to increase. The temperature can be indicated if the temperature relationship of the resistor is known.

To provide the semiconductor component, the semiconductor component is, for example, soldered to the electrically conductive layer of a DCB substrate or bonded to it using an electrically conductive adhesive. In a special embodiment of the production method, to provide the semiconductor component on the substrate, the semiconductor component is arranged on the substrate in such a way that the electrical contact is facing away from the substrate, and one layer of electrically insulating material is applied to the semiconductor component and the substrate in such a way that the electrical contact is freely accessible. A variety of methods are conceivable for achieving this. For example, a mask is applied to the contact surface of the semiconductor component before the electrically insulating material is applied. The electrically insulating material is then applied, for example, by spraying, printing or by vapor deposition. The vapor deposition can be physical (physical vapor deposition) and/or chemical (chemical vapor deposition). On completion of the application, the mask is removed, whereby a contact surface of the semiconductor component that is free from electrically insulating material is obtained.

In a special embodiment, a complete layer of the electrically insulating material is applied and the contact is exposed after application by opening a window in the layer of electrically insulating material. A photo-sensitive electrically insulating material that is exposed to light after application is, for example, used for this purpose. The subsequent etching away of the parts exposed to light expose the contact surfaces of the semiconductor components.

In a particular embodiment, a film of electrically insulating material is applied to the substrate and the semiconductor component by lamination. The film consists, for example, of polyimide (PI), polyethylene (PE), polyphenol or polyetherethketone (PEEK). An epoxide-based film is also conceivable. Advantageously, a film is used that is free, or almost free, from halogens.

The lamination takes place preferably under vacuum in a vacuum press. A particularly close and firm contact between the film and the semiconductor component or substrate is thus produced. To improve the close connection between the film and semiconductor component, or between the film and substrate, a conditioning step under vacuum can take place during and/or after laminating the film in place.

After the electrically insulating material is applied, a window is produced to expose the contact surface of the semiconductor component. In this case, the window consists particularly of at least sixty percent of the size of one side and/or the surface of the semiconductor component. For a large-area contact, the window is particularly at least eighty percent of the side and/or surface of the semiconductor component. The method is thus particularly suitable for power semiconductors, for which a window and a contact surface with a corresponding size is produced by the contacting with a flat conductor. The window is, particularly, opened at the largest and/or side of the semiconductor component facing away from the substrate and preferably has an absolute size of more than 50 mm2, especially more than 70 mm2 or even more than 100 mm2.

The window is, for example, produced by photo-lithography. The window is preferably produced by laser ablation. A CO2 laser with an emission wavelength of 9.24 μm is, for example, used for this purpose.

After the opening, or the exposing, of the contact surface of the component, an electrically conductive material is applied. Application is, for example, by spraying, printing and/or by vacuum deposition of the electrically conductive material in the form of thin layer. To increase the current-carrying capacity, a further electrically conductive material can be applied to this thin, electrically conductive layer. For example, copper is galvanically deposited on the thin layer. The soldering of an electrically conductive film in place is also conceivable. The electrically conductive film is, for example, textured, thus producing a connection line with different line diameters.

The described method, particularly the method whereby the electrically insulating film is laminated in place and the electrically conductive material applied, can be performed several times. This results in a multilayer construction with a multilayer wiring in which any discrete passive electrical components, preferably multilayer components, can be integrated at the same time. In this manner, an electrically passive component of complicated construction can be simply arranged on the substrate. Thus, for example, a multilayer capacitor can be produced on the substrate.

By means of an expansion of the individual steps of the method, further functional components, for example thermal through contacts (vias) can be produced through a layer of the electrical insulating material. By connecting to a heatsink, the heat produced during the operation of the semiconductor component can thus be efficiently dissipated. The integration of electrically conductive layers that provide shielding against electrical or magnetic fields is also conceivable. This improves EMC compatibility.

The following is a summary of the particular advantages provided by this invention

The circuit arrangement is compact. This then requires a relatively small space.

The circuit arrangement can be easily produced.

In addition to the electrical connection line and the discrete passive electrical component, further functional components can also be easily integrated.

The invention is explained in more detail in the following with the aid of exemplary embodiments and the associated illustrations. The illustrations are schematic and are not to scale.

### BRIEF DESCRIPTION OF THE DRAWINGS

These and other objects and advantages of the present invention will become more apparent and, more readily appreciated from the following description of the preferred embodiments, taken in conjunction with the accompanying drawings of which:

FIG. 1 is a side cross-section of a circuit arrangement

FIG. 2 shows a discrete passive electrical component in the form of a multilayer capacitor

FIGS. 3A and 3B are a side view and a plan view of an integrated current sensor

FIG. 4 shows a circuit arrangement with thermal through contacts.

### DETAILED DESCRIPTION OF THE PREFERRED EMBODIMENT

Reference will now be made in detail to the preferred embodiments of the present invention, examples of which are illustrated in the accompanying drawings, wherein like reference numerals refer to like elements throughout.

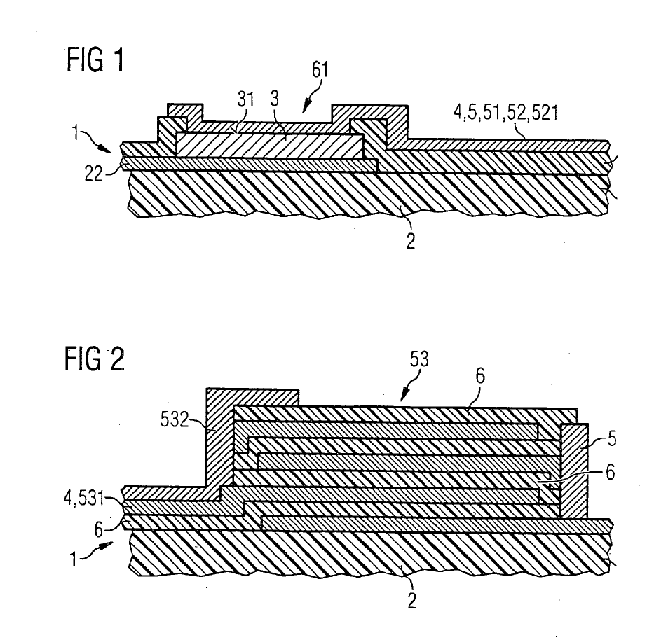

FIG. 1 shows a circuit arrangement 1 of a power semiconductor and a discrete passive electrical component 5 on a substrate 2. The substrate 2 is a DCB substrate with a ceramic carrier layer 21 and a copper electrically conductive layer 22 applied to the carrier layer 21.

A power semiconductor component 3 in the form of a MOSFET is soldered to the copper electrically conductive layer 22 in such a way that a contact surface 31 of the power semiconductor component is facing away from the substrate 2. One of the contacts of the power semiconductor component 3 is electrically contacted through the contact surface 31.

A connection line 4 on the substrate 2 is provided for electrical contacting of the contact surface 31 of the power semiconductor component 3. The connection line 4 in this case serves not only to provide electrical contacting of the contact surface 31 of the semiconductor component 3. The connection line 4 is also a part 51 of a discrete passive electrical component 5.

To provide the circuit arrangement 1, the power semiconductor component 3 is soldered to the electrically conductive layer 22 of the DCB substrate 2 in such a way that the contact surface 31 of the power semiconductor component 3 is facing away from the substrate 2. As an alternative to this, the power semiconductor component 3 is bonded to the electrically conductive layer 22 of the DCB substrate 2 by means of an electrically conductive adhesive. Furthermore, a film 6 based on polyimide is laminated, under vacuum, onto the contact surface 31 of the semiconductor component 3 and substrate 2. This creates a close connection between the film 6 and the semiconductor component 3 or the substrate 2. The film 6 joins to the semiconductor component 3 and the substrate 2 in such a way that a contour is described that is essentially the shape of the semiconductor component 3.

Furthermore, a window 61 is opened in the film 6 by laser ablation using a CO2 laser. This exposes the contact surface 31 of the power semiconductor component. A thin layer of electrically conductive material consisting of a titanium-copper alloy is then produced by deposition from the vapor phase on to the contact surface 31 and a layer of electrically insulating material is produced on areas of the film 6. An electrically conductive adhesive layer of titanium is then applied, followed by an electrically conductive layer of a titanium-tungsten alloy that functions as a diffusion barrier. To increase the current carrying capacity, a layer of copper is then galvanically deposited on the titanium-tungsten alloy layer. A Ti/TiW/Cu sequence of layers is produced, with the connection line 4 and the discrete passive electrical component 5 being formed concomitantly.

### EXAMPLE 1

The discrete passive electrical component 5 is a wire resistor 521 of an electrical resistor 52 (FIG. 1). The wire resistor 521 is formed by thinned areas of the connection line 4 and functions as a fusible link.

### EXAMPLE 2

The discrete passive electrical component 5 is a multilayer capacitor 53 and the connection line 4 functions as an electrode 531 of the multilayer capacitor (FIG. 2). To produce the multilayer capacitor 53, several films of electrically insulating material are laminated in place. A layer of electrically conductive material is produced on the laminated film 6 after each lamination, thus producing the multilayer capacitor 53. Alternatively, films 6 of an electrically insulating material, that are already provided with a layer of electrically conductive material, are applied by lamination. The “external electrodes” 532 required for the electrical contacting of the “inner electrodes” of the multilayer capacitor can be formed by the layers of electrically conductive material. Alternatively, the external electrodes 532 are produced by screen printing after the multilayer structure has been created. The external electrodes 532 are, in accordance with a further form of embodiment, reinforced by the galvanic deposition of copper.

### EXAMPLE 3

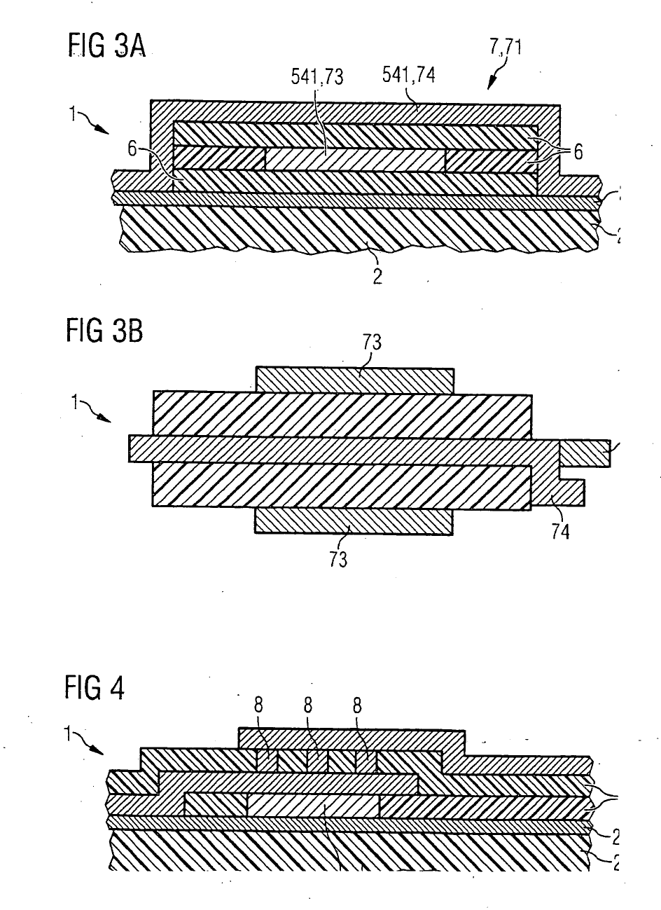

The discrete passive electrical component 5 is a winding 541 of a coil 54, that is itself a part 71 of a sensor 7 (FIGS. 3A and 3B). The sensor 7 is a current sensor 72. The current sensor consists of two magnetically coupled loops 73 and 74 formed by windings, that are applied to the substrate 2 using the technique described above. The loops 73 and 74 are each reinforced by galvanically deposited copper.

### EXAMPLE 4

By means of the connecting and contacting technique described, further functional components are integrated into the multilayer construction (FIG. 8). These further functional components are thermal through-contacts 8, that are produced in the film 6, after the relevant film has been laminated in place, by opening windows and filling the windows with thermally conductive material. These thermal through-contacts 8 have a thermally conducting connection to a heatsink (not illustrated).

The invention has been described in detail with particular reference to preferred embodiments thereof and examples, but it will be understood that variations and modifications can be effected within the spirit and scope of the invention covered by the claims which may include the phrase “at least one of A, B and C” as an alternative expression that means one or more of A, B and C may be used, contrary to the holding in Superguide v. DIRECTV, 69 USPQ2d 1865 (Fed. Cir. 2004).

1-10. (canceled)

11. A circuit device provided on a substrate and comprising:
a semiconductor component arranged on the substrate and having an electrical contact surface; and
at least one connection line on the substrate to contact with the contact surface of the semiconductor component,
wherein
the electrical connection line is part of at least one discrete passive electrical component arranged on the substrate.

12. The circuit device in accordance with claim 11, wherein
the discrete passive electrical component is a capacitor, and
the electrical connection line is an electrode of the capacitor.

13. The circuit arrangement in accordance with claim 11, wherein
the discrete passive electrical component is a coil, and
the electrical connection line is a winding of the coil.

14. The circuit device in accordance with claim 11, wherein
the discrete passive electrical component is an electrical resistor, and
the electrical connection line is a wire resistor.

15. The circuit device in accordance with claim 11, wherein the discrete passive electrical component is a part of a sensor of a physical variable.

16. The circuit arrangement in accordance with claim 11, wherein the semiconductor component is a power semiconductor component.

17. The circuit device in accordance with claim 16, wherein the power semiconductor component is selected from the group consisting of MOSFETs, IGBTs and bipolar transistors.

18. The circuit device in accordance with claim 14, wherein the discrete passive electrical component is a part of a sensor of a physical variable.

19. The circuit arrangement in accordance with claim 18, wherein the semiconductor component is a power semiconductor component.

20. The circuit device in accordance with claim 19, wherein the power semiconductor component is selected from the group consisting of MOSFETs, IGBTs and bipolar transistors.

21. A method for producing a circuit device, comprising:
producing a semiconductor component on a substrate, the semiconductor component having an electrical contact surface facing away from the substrate; and
producing an electrical connection line that contacts the contact surface of the semiconductor component, the electrical connection line being part of a discrete passive electrical component.

22. The method in accordance with claim 21, wherein
the electrical connection line contacts the contact surface at an electrical contact,
the electrical contact faces away from the substrate, and
a layer of electrically insulating material is provided on the semiconductor component and the substrate in such a way that the electrical contact is exposed.

23. The method in accordance with claim 22, wherein a complete layer of electrically insulating material is first applied, and then the electrical contact is exposed by opening a window in the electrically insulating material.
